(19) United States
(12) Patent Application Publication
(10) Pub. No.: US 2025/0137135 A1
(43) Pub. Date: May 1, 2025

(54) Susceptor Assembly for a Chemical Vapor Deposition Reactor

(71) Applicant: MetOx International, Inc., Houston, TX (US)

(72) Inventors: Shahab KHANDAN, Trabuco Canyon, CA (US); Nagaraja Roy SHASHIDHAR, Houston, TX (US); Steven Roy BURDETTE, Horseheads, NY (US); Abhijit RAO, Painted Post, NY (US); Thao NGUYEN, Painted Post, NY (US)

(21) Appl. No.: 18/835,514

(22) PCT Filed: Feb. 27, 2023
(86) PCT No.: PCT/US2023/013916

§ 371 Date: Aug. 2, 2024

Related U.S. Application Data
(60) Provisional application No. 63/314,603, filed on Feb. 28, 2022.

(51) Int. Cl. C23C 16/458; C23C 16/44

(52) U.S. Cl. CPC C23C 16/4586; C23C 16/4404; C23C 16/4581; C23C 16/4585

(57) ABSTRACT

A thermally stable susceptor assembly used in a deposition reactor provides heat input and controls the temperature of a substrate tape as well as minimizes the build-up of errant deposition material. The susceptor heats a substrate tape within the reactor upon which one or more thin films are deposited, particularly high temperature superconductor (HTS) thin films produced in a MOCVD reactor.

### CROSS REFERENCE TO RELATED APPLICATIONS

This application is a national stage application from PCT Application PCT/US23/13916 filed Feb. 27, 2023, entitled “Susceptor Assembly for a Chemical Vapor Deposition Reactor” which claims priority and benefit from U.S. Provisional Patent Application No. 63/314,603 filed on Feb. 28, 2022, entitled “Heater Assembly for Light Assisted MOCVD,” the content of which is incorporated in its entirety herein by reference.

### BACKGROUND OF THE INVENTION

### Technical Field

Embodiments of the subject matter disclosed herein generally relate to susceptor assemblies and systems utilizing said susceptors in a deposition reactor and more particularly in vapor deposition reactors for fabricating high-temperature superconductors on substrate tapes.

### Discussion of the Background

High temperature superconductors (HTS) provide the potential for development of superconductor components at higher operating temperatures compared to traditional superconductors that operate at liquid helium temperature (4.2 K). Superconductors operating at the higher temperatures thus provide the ability to develop superconducting components and products more economically. Thin film HTS material comprised of YBa₂Cu₃O₇₋ₓ (YBCO), is one of a group of oxide-based superconductors. After the initial discovery of YBCO superconductors, other superconductors were discovered having a similar chemical composition but with Y replaced by other rare earth elements. This family of superconductors is often denoted as REBCO where RE may include Y, La, Nd, Sm, Eu, Gd, Tb, Dy, Ho, Er, Tm, Yb or Lu. This material formed the basis for second generation or “2G” HTS wire technology which provides a more cost-effective material for manufacturing HTS tapes and wires.

Such HTS films are typically deposited as textured REBCO thin films which may include one or more buffer layers onto an atomically textured metal substrate. In the case of MOCVD, an organic ligand may comprise a vapor phase precursor delivered to the substrate for deposition. In the manufacturing of High Temperature Superconductors (HTS) via chemical vapor deposition (CVD) or metal-organic chemical vapor deposition (MOCVD) processing, a stainless steel or Hastelloy substrate tape is heated to high temperature, for example, 800° C. to 900° C. for the vapor phase precursor materials to deposit on the substrate tape and HTS film growth to occur.

There are different devices and methods for heating a substrate tape, including IR lamps that heat the tape via radiation, and hot block susceptors that directly contact the substrate tape and provide the needed heat via conduction. A typical CVD reactor 100 is shown in FIG. 1 and includes using a hot block type susceptor 110 that supports and heats a translating substrate tape 120. Reactor 100 is maintained at vacuum via an outlet port 130 and precursor reactant(s) 140 are introduced via a showerhead 150.

Existing heated susceptors in a CVD process particularly for HTS production have several disadvantages including high temperature gradients within the reactor, and errant deposition that builds up on the exposed surfaces of the susceptor and other components of the reactor.

One limitation to achieving desirable thermal control is that the spacing between the showerhead and the deposition surface may be very small, for example 5 mm to 30 mm, making it difficult to illuminate the deposition surface to the high intensity levels required for the process. The surface of the shower head may be e.g., 300-350° C., while the surface of the deposition area may typically be around 850-900° C., making for very high temperature gradients of, for example, 500° C. or more over the small gap between the showerhead and the top of the susceptor. Compounding the temperature control challenges, is that cooler precursor and carrier gases flowing from the showerhead cool both the susceptor and substrate. The deposition process is thus very sensitive to temperature changes and needs to be maintained at, for example, within approximately a 5-10° C. range for acceptable deposition performance.

In a typical MOCVD HTS process, the reactant precursor gases tend to deposit upon other surfaces within the reactor chamber where the surface temperature is above approx. 400-450° C. To keep the chamber clean, it is thus critical to maintain internal surfaces at a minimum, or at least below approximately 400° C. to prevent errant deposition which is deposition occurring on surfaces other than the intended substrate. Particularly in CVD reactors under vacuum, precursor vapor undergoes expansion and is prone to deposit on exposed surfaces of the susceptor outside the intended target deposition zone on the tape where HTS film growth is desired. Over long process times, the errant material deposited on the susceptor may build up to exceed the tape thickness that may be between 30 to 100 micrometers (um) thickness, for example. Such errant deposition buildup on susceptor surfaces near the tape edges themselves can cause degradation to the properties of the HTS film grown on the tape. For example, the precursor boundary layer flow uniformity on and around the tape may be impacted by errant deposition. The heat transfer and the radiation properties of the errant material build-up may be different than the HTS film which can cause local edge temperature non-uniformity on the tape which affects the HTS film properties. Also, the built-up material itself may break away, become entrained within micro-eddies, and redeposit on and foul or disturb the deposited layers causing performance degradation of the HTS film.

Finally, errant material build-up on the susceptor is a major limiting factor in the ability to run continuous and lengthy HTS process runs. Primarily, the build-up prevents the system from processing kilometers long HTS tapes due to a need to stop processing and disassemble the reactor for cleaning. For these reasons, new susceptor assemblies and systems are needed to tightly control thermal conditions as well as errant deposition particularly in areas proximal to the target tape substrate.

### SUMMARY OF EXAMPLE EMBODIMENTS

According to an embodiment, there is a susceptor assembly for heating and temperature control of a substrate tape within a deposition apparatus that includes a longitudinal susceptor block for heating at least one longitudinal substrate tape, a refractory element adjacent to a side of the susceptor block, a radiation shield surrounding one or more sides of refractory element, and at least one heater element coupled to susceptor block with at least a portion of the heater element extending to the exterior of susceptor assembly.

According to another embodiment, there is a susceptor assembly for heating and temperature control of a substrate tape within a deposition apparatus that includes a longitudinal susceptor block for heating at least one longitudinal substrate tape, a refractory element adjacent to a side of the susceptor block, a radiation shield surrounding one or more sides of the refractory element, and at least one heater element coupled to susceptor block with at least a portion of the heater element extending to the exterior of susceptor assembly. The susceptor assembly also has two or more adjacent raised sections that extend vertically from the upper surface of the susceptor block which are separated by a gap from an adjacent raised section thus forming a channel to collect errant deposition material from between adjacent longitudinal substrate tapes.

According to yet another embodiment there is a reactor system for photo-assisted deposition of thin films that includes a chemical vapor deposition apparatus with a reactor housing having an inlet showerhead for introducing a precursor, a vacuum exhaust, and an illumination source. A susceptor assembly is located within the reactor housing for heating a longitudinal substrate tape. The susceptor assembly has a longitudinal susceptor block, a heater element coupled to the susceptor block, a refractory element and a radiation shield. A longitudinal substrate tape translates along the top of the susceptor block and below the inlet showerhead.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 shows a prior art reactor assembly with a hot block type susceptor.

FIG. 2 shows a 2D cross section of an exemplary susceptor assembly of the present disclosure having refractory and shielding elements among other features disclosed in the detailed description.

FIG. 3A shows a 2D cross section of an exemplary susceptor assembly of the present disclosure having refractory and shielding elements, as well as channels for collection of errant deposition particles among other features disclosed in the detailed description.

FIG. 3B shows an expanded view in 2D cross section of the channel related detail of the susceptor assembly shown in FIG. 3A.

FIG. 4 shows an expanded view in 2D cross section of protrusion related details of the susceptor assemblies shown in FIGS. 2 and 3A.

FIG. 5A shows an expanded view in 2D cross section of channel and protrusion related details of the susceptor assembly shown in FIG. 3A.

FIG. 5B shows a top-down view of channel and protrusion related details of the susceptor assembly shown in FIG. 3A.

FIG. 5C shows a top-down view of an alternative embodiment of the channel and protrusion related details of the susceptor assembly shown in FIG. 3A.

FIG. 6 shows an exemplary graph of the thermal performance characteristics of the presently disclosed susceptor assemblies.

FIG. 7 shows a 2D cross section of an exemplary photo-assisted CVD reactor system employing the susceptor assemblies of the present disclosure among other features disclosed in the detailed description.

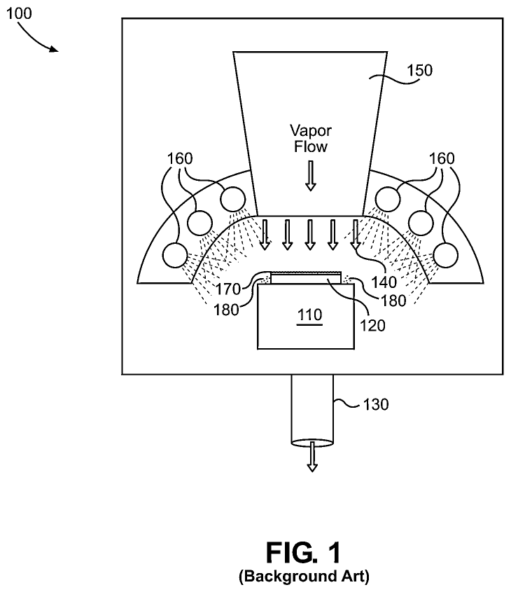

### DETAILED DESCRIPTION OF EXAMPLES OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to susceptor assemblies and systems for deposition of thin films, particularly superconducting coated conductors formed from films deposited on substrate tapes in a CVD and more particularly in a MOCVD reactor. However, the embodiments discussed herein are not limited to such elements. For example, the susceptor assemblies disclosed herein have application to other reactor types that utilize a susceptor for heating a substrate and where build-up or errant deposition may be a problem. Such other reactor types may include, but are not limited to, Pulsed Laser Deposition (PLD), Rotating Cylinder Reactor (RCE) and others.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. The drawings are intended to be illustrative of the claimed features and unless stated otherwise are not to scale. Where a dimension of a given feature may be pertinent, the detailed description will indicate one or more examples of the range and units of said dimension where needed to enable the subject matter. Further, the described features, structures or characteristics may be combined in any suitable manner in one or more embodiments.

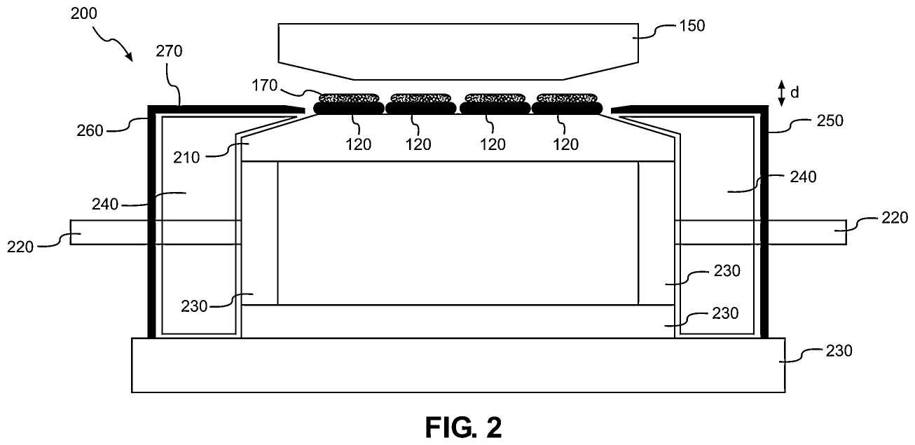

An exemplary susceptor assembly 200 for heating and temperature control of a substrate tape 120 within a deposition apparatus is shown in FIG. 2. A susceptor block 210 of susceptor assembly 200 is positioned below a showerhead 150 by a vertical distance “d” such that a thin film layer 170 is deposited on one or more substrate tapes 120 (four are shown) which translate on top of susceptor block 210. Susceptor block 210 may be manufactured from any suitable metal or metal alloy such as Inconel that is machinable and has a suitable thermal conductivity, or alternatively may be composed of Silicon Carbide (SiC). Susceptor block 210 is shown as a generally trapezoidal shaped solid cross-section with its length depicted out of the page, however, block 210 may be any rectilinear shaped cross-section or have a combination of straight edges and curved shoulders etc. In preferred embodiments, susceptor block 210 is longitudinally shaped with a length greater than the width where the length determines a deposition zone length within a reactor chamber (to be discussed below). The width of the uppermost face of block 210 is dependent upon the number and widths of substrate tapes 120 utilized. In another embodiment, the top surface of longitudinal susceptor block 210 may be curved in the lengthwise direction such that the vertical height of the susceptor block is greater at the center to provide tension to the substrate tape as it translates across the susceptor block.

For illustrative purposes, FIG. 2 shows four substrate tapes 120 in contact with susceptor block 210, but any number of tapes is contemplated by the present disclosure. Furthermore, one or more tapes 120 may re-route via a reel-to-reel system through the deposition zone and thus contact susceptor block 210 more than once. PCT Patent Application WO2022/182967 owned by the present Applicant entitled “Multi-Stack Susceptor CVD Reactor for High-Throughput HTS Tape Manufacturing” is incorporated herein for all purposes and discloses several substrate tape routing systems and methods that include, for example, multi-susceptor and multi pass arrangements. Thus, tape handling configurations described herein may encompass a “single-pass” tape configuration, or a single-length tape with “multi-pass” tape configuration, or several separate tapes running in parallel over susceptor block 210 in a “multi-track” configuration. The reels or rollers (not shown) that are used in single or multi-pass configurations may be located inside the reactor, or outside the reactor with the one or more substrate tapes 120 passing through slits or ports in the reactor walls.

Susceptor block 210 is heated with one or more heater elements 220 (two are shown) which may be resistive type heater elements that heat block 210 by direct contact to temperatures of 900-1200° C. or higher. Heater elements 220 may be comprised, for example, of a metal, a metallic alloy e.g., Haynes 214, or of silicon carbide (SiC) material.

One or more refractory elements 230 of a given length, width and thickness may be positioned adjacent to susceptor block 210 and provide a thermal barrier between the susceptor block and other components of the susceptor assembly 200. The length and width of refractory elements 230 are such that substantially the length and width of at least one side of the susceptor block 210 is insulated. Thickness may be, for example, a few millimeters or a 1 cm or more as needed dependent upon the material selected. For example, refractory elements 230 may typically be comprised of a material that is stable at high temperatures and may be polycrystalline, polyphase, inorganic, metallic, metallic alloy, or non-metallic, and may be porous and heterogeneous or multi-layered of non-heterogenous materials. They are typically composed of oxides, carbides, nitrides etc. of the following materials: silicon, aluminum, magnesium, calcium, boron, chromium and zirconium, for example a ceramic material as an oxide of aluminum (alumina) or silicon (silica) designed to withstand high temperatures in excess of e.g., 500° C. As shown in FIG. 2, refractory elements 230 are comprised of individual blocks adjacent to a side of susceptor block 210. In other examples, refractor elements 230 may be machined, molded, or formed as a single element to remove gaps and further enhance thermal barrier properties. In the context of the present disclosure, “refractory”, “refractories”, “refractory material”, “refractory block”, “refractory element or elements” shall mean any material or combination of materials that provides a thermally insulative barrier. The material may also impart one or more additive or different properties e.g., additional insulative or thermal resistance and/or structural strength, and thus refractory element or elements 230 may be multi-component in nature with different components comprised of the same or different materials, thicknesses and densities. For example, as shown in FIG. 2, refractory element(s) 230 surround multiple sides of susceptor block 210 providing both thermal and structural benefits. Side refractory elements 230 position and support susceptor block 210 and a lowermost element 230 provides a base of support for the entire susceptor assembly 200. Additional outside refractory elements 240 provide an additional insulative layer to innermost elements 230. Thus, in this example, a two-component set of refractory elements 230/240 is utilized whereby one component 230 provides a thermal barrier as well as, owing to its rigidity, e.g., a solid ceramic, they also provide structural support to susceptor block 210. Outer positioned additional elements 240 provides added insulation and thus may be comprised of a different and lighter material without rigidity, e.g., ceramic wool.

Also shown in FIG. 2, a radiation shield 250 comprised of a single shaped sheet or more than one individual sheets or plates of thin metal, metal alloy or ceramic composition surrounds refractory element 230 on more than one side, and in certain embodiments, encompasses the entirety of susceptor assembly 200 save the uppermost face or surface of susceptor block 210. Radiation shield 250 may further include a low emissivity coating 260 on the inside surfaces (the side facing the refractory 230/240) and/or a high emissivity coating 270 on the outside surfaces. This shielding reflects heat from the susceptor 210 but cools quickly due to the high emissivity coating 270 on the outside. Though the temperature of the inside of the susceptor assembly 200 may exceed e.g., 1200° C., the temperature of the radiation shield 250 outside surfaces may be substantially less, around 350° C., for example. This reduced external temperature prevents or minimizes errant deposition on the outside of the susceptor assembly 200. Thus, the only surfaces exposed to high temperatures are preferably limited to the deposition surface, i.e., the substrate tape(s) 120.

The preferred embodiment for a low emissivity coating 260 may be a gold or silver coating or an alloy thereof coated on the inside. An exemplary high emissivity coating 270 on the outside may be any vacuum compatible physical vapor deposited black body enhancing coating, e.g., a high temperature black paint.

It is preferred that deposition occur only upon the substrate tape(s) 120 which are in thermal contact with the susceptor block 210. However, since there is a gap between the tapes 120, errant deposited material may build up within this gap during the run which can interfere with the desired coating formation and diminish the quality and performance of the thin film, particularly in the case of high temperature superconductors (HTS). PCT Patent Application WO2022/182967 owned by the present Applicant entitled “Susceptor for a Chemical Vapor Deposition Reactor” is incorporated herein for all purposes and discloses various embodiments which include grooves along the length of the susceptor block such that there is a trench or channel that runs lengthwise in between adjacent substrate tapes thus forming a gap between the tapes to capture errant deposition particles in these regions.

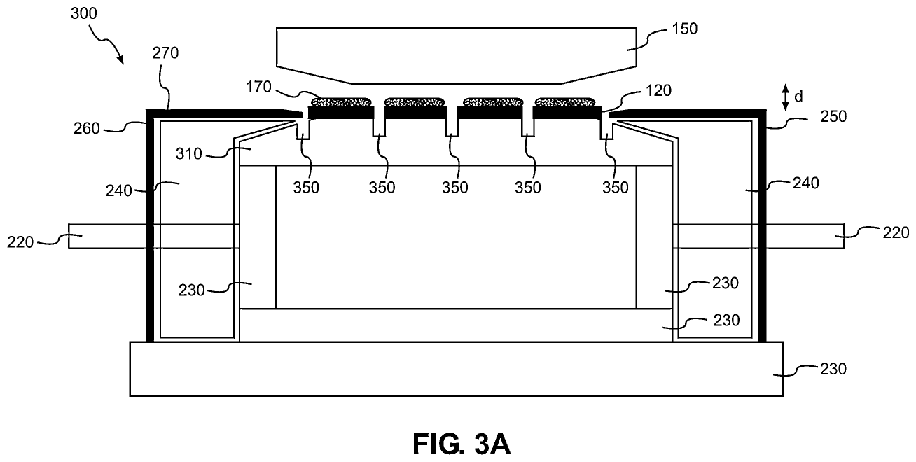

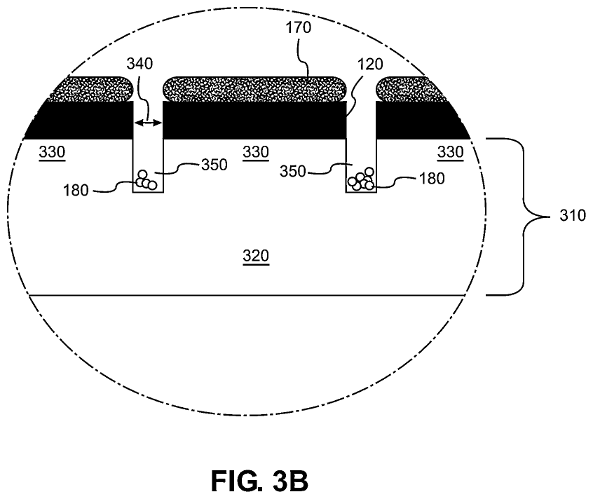

An exemplary susceptor assembly 300 for heating and thermal control of substrate tapes 120 which also controls errant deposition is shown in FIG. 3A. In this embodiment, susceptor assembly 300 is comprised of a susceptor block 310 having channels 350 in between substrate tapes 120 for collection of errant deposition material 180. Note that similar to the embodiment shown in FIG. 2, susceptor block 310 is shown to support four substrate tapes 120, but the susceptor assembly and tape handing system may also be configured to support fewer or more than four substrate tapes 120 and/or multiple passes of the same or multiple substrate tapes 120. Further, in the case of a single substrate tape 120, susceptor block 310 may include two channels 350 with one located on either side of a single raised section 330.

The channel detail is shown in FIG. 3B, where two or more raised sections 330 extend vertically from main body 320 of susceptor block 310 and extend lengthwise along the length of susceptor block 310 which is shown as out of the page in the figures. Each raised section 330 is separated from an adjacent raised section by a gap 340 with a prescribed width and depth that forms a channel 350. Raised sections 330 are preferably of the same composition as the main body 320 and may be machined, cast, or milled from a single block of material. Other techniques may include laser etching or band saw cutting to produce gaps 340. In other embodiments, it is possible to have the raised sections 330 separate from but coupled to the main body 320 with the raised sections 330 composed of the same material as main body 320 or of a different material with different thermal conductivity. In this case, the raised sections 330 may be attached to the main body 320 using different methods; examples include screws or high temperature bonding agents.

The width of the top surface of raised section 330 is preferably the same or less than the width of substrate tape 120. For example, in certain embodiments, for a single substrate tape 120 which is nominally 12 mm wide, and thus raised section 330 is 12 mm wide. In other embodiments, raised section 330 may be slightly less in width allowing for a small overhang and thus the top surface may be 10-11 mm wide. Hot block susceptor 310 thus contacts and conductively heats substantially the full width of substrate tape 120 without having a portion of the top surface of raised section 330 exposed and susceptible to build-up of errant deposition 180.

The dimensions of channel 350 may be of greater or less depth, for example, 0.5 mm, 1 mm, 2 mm or more to accommodate greater volumes of errant deposition material 180 which may accumulate to greater degree depending on run time, deposition efficiency and other reactor design characteristics. Furthermore, channels may be a rectilinear or other shape, for example, hemispherical in cross-section. Given that substrate tape 120 is translating and in frictional contact with raised section 330 that is the same or less width; substantially no deposition material 180 adheres to a raised section 330 or the sides of substrate tape 120 and instead deposits into channel 350. During long process runtimes where errant deposition material 180 may accumulate in channel 350 to a degree that may fill or nearly fill the channel, a purge gas that is suitably inert such as argon or nitrogen may be directed along the channel to push material to an end of the susceptor assembly 300 and out towards an outlet of the reactor.

Similar to the curvature of susceptor block 210 as discussed above and shown in FIG. 2, susceptor block 310 may also include a lengthwise curvature to add tension to substrate tape 120 thereby providing added downward force to aid in consistent susceptor-substrate tape contact and heat transfer.

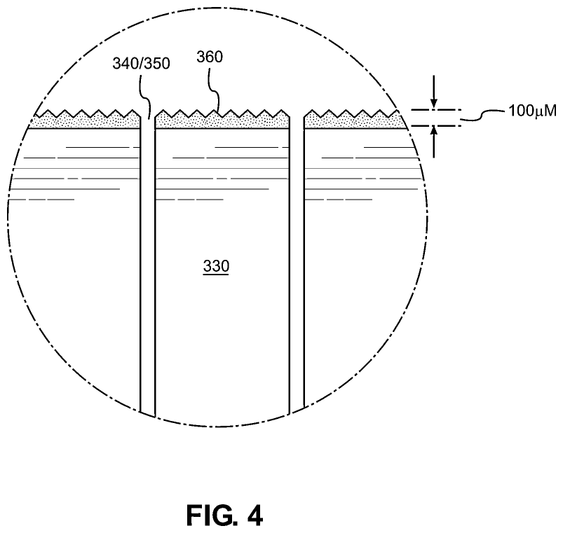

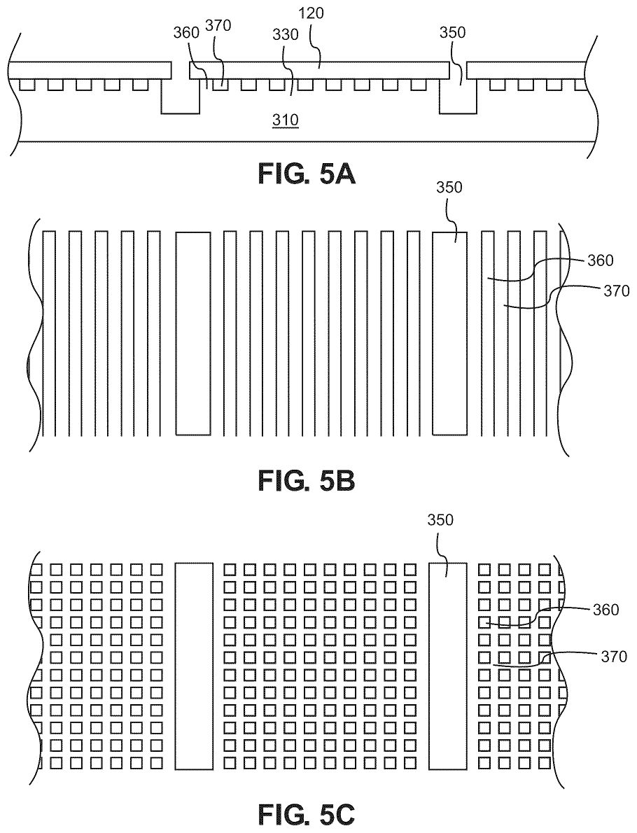

In other embodiments, top surface of raised section 330 may be textured or have protrusions 360 which may be comprised of micro-protrusions, micro-texture, surface imperfections, or gaps to aid in radiative and/or conductive heat distribution to evenly heat the substrate tape 120. For example, as shown in FIG. 4, micro-texture protrusions 360 of approximately 100 microns in height are shown. Other size and density of textures are thus readily contemplated by those skilled in the art having the benefit of the present disclosure, for example, the micro-textured surface may be comprised of protrusions with an average height of 10 or even single digit microns. In yet other embodiments, the protrusions 360 may be larger as shown in FIG. 5 where the protrusions 360 form micro-channels 370 with aspect ratios (width and depth) at fractions of size smaller than channels 350 in between adjacent substrate tapes 120. For example, the micro-channels 370 may be one-fourth the height of a channel 350. Further, protrusions 360 may run continuously down the length of a susceptor block 310 as shown in the top-down view of FIG. 5B, but also may include breaks in the longitudinal direction thus creating grids of various patterns as given in (top-down view) FIG. 5C.

The growth mechanism occurring during the deposition of thin films on a substrate tape 120 and a susceptor (210/310) will be discussed in order to describe the operation and benefits of channels 350. With reference to FIG. 3A, to be discussed in greater detail later, the precursor chemicals are transported by the main inlet gas flow showerhead 150 to the substrate tape(s) 120 after which the reaction and product deposition occurs chiefly inside the laminar flow boundary layer on and around the substrate. The boundary layer for example may be similar to the boundary layer of flow over a flat plate. Thus, deposition within the laminar boundary layer uniformly deposits particles over the exposed susceptor surfaces between tapes. When channels 350 are added to the susceptor block 310, the laminar flow boundary layer is disturbed with discontinuities at those locations on the susceptor. Another benefit of the channels includes, for example, that particles flowing into a channel get trapped and tend to remain inside the channel in a circulatory motion until they eventually adhere and are deposited upon an interior wall surface of the channel. Hence adding channels 350 to the susceptor aids in the minimization of particle build-up on the susceptor surfaces between tapes which in turn prevents loose particles from potentially fouling the thin film.

Given that a high degree of thermal stability of the susceptor block (210/310) is key to obtaining desired thin film characteristics as well as minimizing errant deposition; the thermal control features (e.g., refractories 230 etc.) and susceptor channels 350 of susceptor assembly 300 work in conjunction. Returning to FIG. 3A, the thermal control aspects described above relative to susceptor assembly 200 are similarly provided in the channeled susceptor assembly 300. Briefly, susceptor assembly 300 thus includes a longitudinal susceptor block 310 for heating at least one longitudinal substrate tape 120; one or more refractory elements 230 is positioned adjacent to at least one side of the susceptor block 310; a radiation shield 250 surrounds one or more sides of refractory element 230; and at least one heater element 220 is coupled to susceptor block 310, wherein at least a portion of the at least one heater element 220 extends to the exterior of susceptor assembly 300.

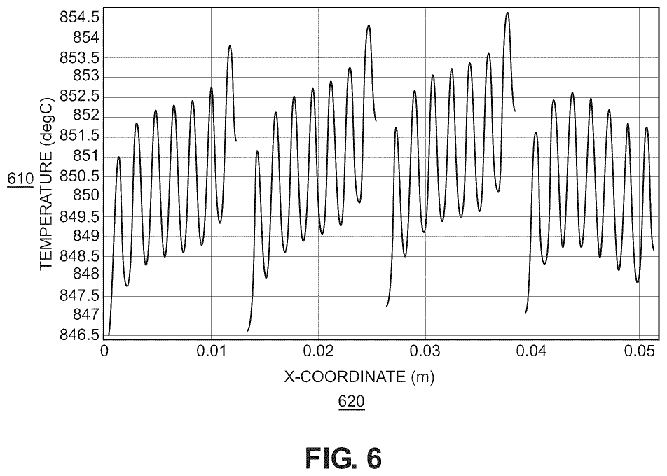

Conventionally, two smooth rigid surfaces would be expected to provide the maximum contact and thus yield the greatest thermal stability. However, high thermal stability of a channeled susceptor assembly 300 could be achieved despite the changes to the surface of the upper region of susceptor block 310. FIG. 6 shows an exemplary thermal simulation of a multi-tape channeled 350 susceptor block 310 with micro-channels 370 indicating an approximate 5° C. temperature (y-axis, 610) oscillation and gradient over the width (x-axis, 620) of each of four substrate tapes 120 which is within the thermal stability target.

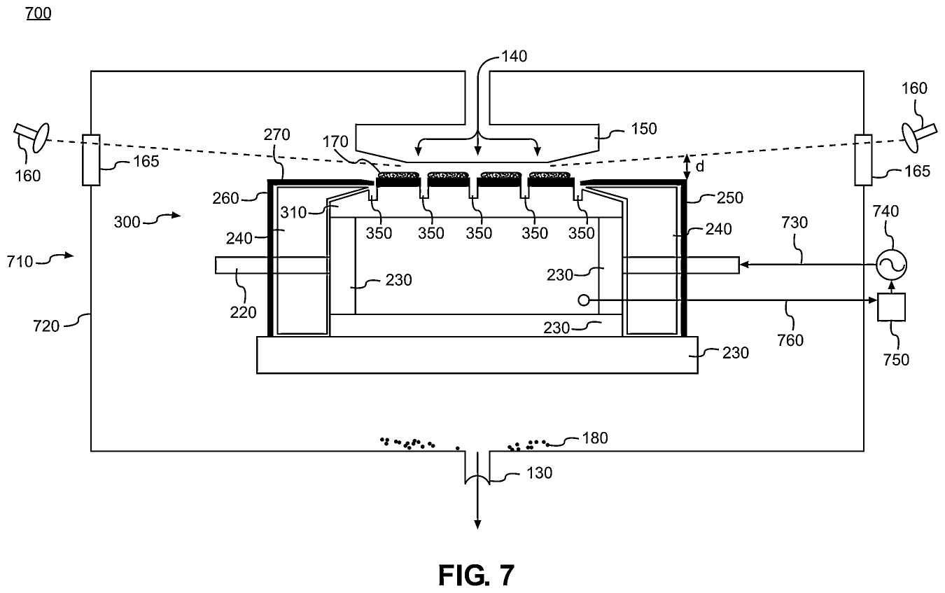

An exemplary reactor system 700 that utilizes susceptor assembly 300 for controlling the temperature of a substrate tape(s) 120 as well as minimizing the effects of errant deposition 180 is shown in FIG. 7. In this example, reactor system 700 includes reactor apparatus 710 which includes susceptor assembly 300 as described above and shown in e.g., FIG. 3; however, it is to be understood that susceptor 200 also as described above and in FIG. 2 may be installed into reactor apparatus 710 in a similar manner. Also, system 700 and deposition apparatus 710 are discussed with specific reference to a preferred embodiment of a MOCVD reactor for thin film production of HTS films. However, it is to be understood that other thin films and other deposition reactor types (e.g., CVD) may employ the susceptor assemblies (200/300) described herein.

The reactor apparatus 710 is comprised of a reactor housing 720 of a given length and width where typically the length is greater than the width where the housing 720 for HTS thin film depositions is preferably operated under vacuum conditions maintained by one or more exhaust or outflow ports 130. (The reactor's lengthwise dimension is out of the page in the 2D representation of FIG. 7.) A showerhead 150 for the delivery of one or more precursors 140, e.g., a metal organic compound from an external source (not shown) is included which may be a direct liquid injection vapor source, or a solid precursor feed system as disclosed in U.S. Pat. No. 11,162,171 entitled “Solid Precursor Feed System for Thin Film Depositions” which is assigned to the present Applicant and incorporated by reference herein for all purposes.

In preferred embodiments, radiation or illumination sources 160 are utilized to aid thin film 170 growth on substrate 120 and may be comprised of, for example, single lamps or an array of lamps, LEDs, etc. emitting one or more or a combination of Ultraviolet (UV) to visible wavelengths, but other wavelengths, such as near UV to far infrared bandwidth sources may be utilized. Illumination at the surface of the growing film energetically excites the surface atoms and enhances molecular surface mobility thus allowing for more rapid attainment of a lower energy configuration. In this manner, a photo-activated or photo-assisted deposition process enhances the YBCO deposition rate and improves the crystallization structure of the resulting HTS thin film. In the example of FIG. 7, lamps 160 are positioned external the reactor housing 720 and the radiation transmitted through one or more windows 165 located on one or more walls of the reactor housing 720. In other approaches, lamps 160 may be located inside the reactor housing 710. However, minimizing the distance “d” between showerhead 150 and substrate tape(s) 120 has many advantages, including higher deposition rates and efficiency. Thus, in order to provide sufficient illumination through a small gap “d” necessitates an acute angle which favors placement of radiations sources 160 at further distances. It is also preferred to place the radiation source outside the reactor housing 720 to prevent the illumination source from getting coated by errant deposition which would cause degradation of the illumination power and photo-activation effectiveness. Further, externally placed sources may more easily be cooled via water-to-water heat-exchanger. Hence external sources and use of windows 165 is a preferred embodiment.

In such embodiments with reduced distance “d” between the susceptor and showerhead (e.g., as low as 10 mm, 5 mm, or less) in particular are provided by the present disclosure of susceptor assemblies 200/300 having a high degree of thermal control, owing to the heat transfer characteristics between the susceptor and proximally located showerhead 150. For example, reactor system 700 is thermally stable when it is connected to a heat source as well as a heat sink. The heat sink is the radiative heat transfer from the susceptor to the showerhead which is preferably cooled with fluid circulation, for example an oil or water circulation heat-exchanger maintained at, for example, 300-350° C. and the source is the susceptor top surface and the HTS tape. Thus, stable heat transfer from the susceptor acting as the source to the showerhead acting as the sink across reduced distance “d” improves the temperature control over HTS tape 120. Additionally, and as discussed above, in certain preferred embodiments, this effect may be further enhanced by selective application of emissivity adjusting coatings to various surfaces within the system, particularly the susceptor radiation shield 250 as well as the underside surface of the showerhead 150 facing the susceptor (200/300).

In the system embodiment of FIG. 7, susceptor assembly 300 is shown to support four substrate tapes 120, however, as discussed prior, the susceptor block 310 may be configured to support any number of substrate tapes 120 and/or accommodate multiple passes of the same substrate tape or tapes. Substrate tape 120 payout and take-up reels (not shown) may be located inside the reactor or outside the reactor with the tape(s) passing through sealed ports located on the reactor walls of the housing 720.

System FIG. 7 shows susceptor assembly 300 positioned within reactor housing 720 and is configured to be heated by resistive type heater 220 and provides at least one channel 350 for the collection of errant deposition material 180. As described above, in certain embodiments susceptor assembly 300 or 200 is comprised of a longitudinal (out of the page in FIG. 7) susceptor block 310 or 210 that heats one or more longitudinal substrate tapes 120 within the deposition apparatus 710. At least one (two are shown) heater element 220 is coupled to susceptor block 310 with at least a portion of the heater elements 220 extending to the exterior of susceptor assembly 200 or 300 which is connected to an electrical conduit or busbar 730 that may be located inside reactor housing 720 and ultimately connects to a power source 740 external the reactor. Power source 740 may be controlled by a control system 750 with a proportional integral derivative (PID) or other type of feedback controller capable of receiving inputs from one or more sensors 760 such as a direct contact thermocouple or a non-contact infra-red thermometer. Control system 750 then compares the measured temperature to a predetermined setpoint temperature and adjusts the power input to the susceptor block via power source 740.

Also, susceptor assembly 300 or 200 may include one or more refractory elements 230 that are positioned adjacent to a side of the susceptor block 210/310, and a radiation shield 250 surrounds one or more sides of the refractory element(s) 230. In preferred embodiments, with particular reference to susceptor block 310, the block may additionally include two or more adjacent raised sections 330 that extend vertically from the main body 320 of the susceptor block, and each raised section 330 is separated by a gap 340 from an adjacent raised section 330 and forms a channel 350 to collect errant deposition material 180 from between adjacent longitudinal substrate tapes 120. Further, in the case of a single substrate tape 120, susceptor block 310 may include two channels 350 with one located on either side of a single raised section 330.

Reactor system 700 may be further characterized by the additional features to include but not limited to the following regarding either susceptor assembly 200 or 300 as discussed above and illustrated in FIGS. 2, 3A, 3B, 4, 5A, 5B, and 5C:

The refractory element(s) 230 may be composed of a single or more than one component.

The components of the refractory element(s) 230 may be further comprised of at least one material that is different from a material of another component.

An emissivity coating 260/270 may be applied to one or more portions and/or sides internal or external of radiation shield 250.

The emissivity coating may be applied to additional reactor assembly 710 components e.g., the showerhead 150.

The emissivity coating 260/270 may be a low emissivity 260 or high emissivity coating 270, e.g., a ceramic or black body enhancing coating.

The top surface of the susceptor block 210/310 may be curved in a lengthwise direction such that the vertical height of the susceptor block is greater at the center to provide tension to the substrate tape.

Susceptor blocks 210 and 310 may include protrusions 360, which are inclusive micro-protrusions, texture, micro-texture, gaps or surface imperfections to aid in radiative and conductive heat distribution to aid in evenly heat the substrate tape 120.

Protrusions 360 may additionally form micro-channels 370 beneath substrate tapes 120.

Protrusions 360 may run continuously down the length of a susceptor block 310 or may include breaks in the longitudinal direction thus creating grids of various patterns.

What is claimed is:

1. A susceptor assembly for heating and temperature control of a substrate tape within a deposition apparatus, the susceptor assembly comprising:
a longitudinal susceptor block for heating at least one longitudinal substrate tape;
a refractory element positioned adjacent to a side of the susceptor block;
a radiation shield surrounding one or more sides of refractory element; and
at least one heater element coupled to susceptor block, wherein at least a portion of the at least one heater element extends to the exterior of susceptor assembly.

2. The susceptor assembly of claim 1, wherein the refractory element is composed of more than one component.

3. The susceptor assembly of claim 2, wherein the components of the refractory element are comprised of at least one material that is different from a material of another component.

4. The susceptor assembly of claim 1 further comprising an emissivity coating on a side of the radiation shield.

5. The susceptor assembly of claim 1, wherein the top surface of the longitudinal susceptor block is curved in a lengthwise direction such that the vertical height of the susceptor block is greater at the center to provide tension to the substrate tape.

6. A susceptor assembly for heating and temperature control of a substrate tape within a deposition apparatus, the susceptor assembly comprising:
a longitudinal susceptor block for heating at least one longitudinal substrate tape;
a refractory element positioned adjacent to a side of the susceptor block;
a radiation shield surrounding one or more sides of refractory element; and
at least one heater element coupled to susceptor block, wherein at least a portion of the at least one heater element extends to the exterior of susceptor assembly,
wherein the susceptor block is comprised of two or more adjacent raised sections extending vertically from the upper surface of the susceptor block, and
wherein each raised section is separated by a gap from an adjacent raised section, and
wherein the gap separating adjacent raised sections forms a channel to collect errant deposition material from between adjacent longitudinal substrate tapes.

7. The susceptor assembly of claim 6, wherein the refractory element is composed of more than one component.

8. The susceptor assembly of claim 7, wherein the components of the refractory element are comprised of at least one material that is different from a material of another component.

9. The susceptor assembly of claim 6, further comprising an emissivity coating on a side of the radiation shield.

10. The susceptor assembly of claim 6, wherein the top surface of the susceptor block is curved in a lengthwise direction such that the vertical height of the susceptor block is greater at the center to provide tension to the substrate tape.

11. A reactor system for photo-assisted deposition of thin films within a chemical vapor deposition apparatus, the system comprising:
a chemical vapor deposition apparatus comprising a reactor housing having an inlet showerhead for introducing a precursor, a vacuum exhaust, and an illumination source,
a susceptor assembly located within the reactor housing for heating a longitudinal substrate tape comprising a longitudinal susceptor block, a heater element coupled to the susceptor block, a refractory element and a radiation shield; and
a longitudinal substrate tape configured to translate along the top of the susceptor block and below the inlet showerhead.

12. The system of claim 11, wherein the refractory element is comprised of more than one component.

13. The system of claim 12, wherein the components of the refractory element are comprised of at least one material that is different from a material of another component.

14. The system of claim 11, further comprising an emissivity coating on a side of the radiation shield.

15. The system of claim 11, wherein the top surface of the susceptor block is curved in a lengthwise direction such that the vertical height of the susceptor block is greater at the center to provide tension to the substrate tape.

16. The system of claim 11, wherein the susceptor assembly is further configured for heating more than one longitudinal substrate tape.

17. The system of claim 11, wherein the susceptor block is further comprised of two or more adjacent raised sections extending vertically from the upper surface of the susceptor block, and each raised section is separated by a gap from an adjacent raised section, and wherein the gap separating adjacent raised sections forms a channel to collect errant deposition material from between adjacent longitudinal substrate tapes.

18. The system of claim 11, wherein an upper surface of susceptor block further comprises micro-protrusions, gaps or imperfections that contact the underside of a substrate tape to aid heat distribution to the substrate tape.

19. The system of claim 11, wherein the vertical spacing between the inlet showerhead and substrate tape is less than 50 mm.

20. The system of claim 11, further comprising a controller configured to control heat input to the susceptor assembly such that longitudinal substrate tape is maintained during deposition within 10° C. of a predetermined target temperature.
